(19) United States
(12) Patent Application Publication
(10) Pub. No.: US 2011/0061907 A1
(43) Pub. Date: Mar. 17, 2011

(54) Printed circuit board and method of manufacturing the same

(75) Inventors: Myung Sam Kang, Hwaseong (KR); Chang Sup Ryu, Yongin (KR)

(73) Assignee: SAMSUNG ELECTRO-MECHANICS CO., LTD., Suwon (KR)

(21) Appl. No.: 12/654,538

(22) Filed: Dec. 22, 2009

(30) Foreign Application Priority Data
Sep. 14, 2009 (KR) 10-2009-0086584

(51) Int. Cl. H05K 1/09; H05K 1/11; C25D 5/02; B32B 38/00

(52) U.S. Cl. 174/257; 174/261; 205/125; 156/150

(57) ABSTRACT

A printed circuit board according to an aspect of the invention may include: a board portion having an electrode portion provided on a surface thereof; a solder resist layer provided on the surface of the board portion and having an opening therein to expose the electrode portion to the outside; and a bump layer having the same diameter as the opening and providing an electrical connection with an external chip component.

### CROSS-REFERENCE TO RELATED APPLICATIONS

This application claims the priority of Korean Patent Application No. 10-2009-0086584 filed on Sep. 14, 2009, in the Korean Intellectual Property Office, the disclosure of which is incorporated herein by reference.

### BACKGROUND OF THE INVENTION

1. Field of the Invention

The present invention relates to a printed circuit board and a method of manufacturing the same, and more particularly, to a printed circuit board having a bump layer so that a circuit chip is electrically connected to an upper part of the bump layer, and a method of manufacturing the same.

2. Description of the Related Art

In general, methods of connecting chips to external substrates, such as printed circuit boards (PCBs) or wafer level packages (WLPs), may include a wire bonding method, a tape automated bonding method (TAB), and a flip chip method.

Among these methods, the flip chip method is widely being used in applications ranging from super computers requiring excellent electrical characteristics to portable electronic devices, because the flip chip method can increase speed and power through a short electron pathway, and also increase the number of pads per unit area.

Furthermore, according to the flip chip method, solder bumps are formed on a wafer in order to obtain appropriate bonding between a chip and an external substrate. The technique for manufacturing solder bumps has been developed into a method of manufacturing solder bumps having appropriate conductivity, uniform lengths and fine pitches.

According to the technique for forming solder bumps, the characteristics and the application range of solder bumps depend on what kind of material is being bumped. General solder bump forming techniques may include soldering in which a pad electrode comes into contact with molten solder, screen printing in which solder paste is formed on a pad electrode by screen printing and is subjected to a reflow process, a solder ball method of mounting a solder ball onto a pad electrode portion and reflowing the mounted solder ball, and plating in which solder plating is performed on a pad electrode.

Among them, screen printing has been widely used to form solder bumps in which the process of forming solder bumps in this manner is simple and manufacturing costs are low. However, as for the screen printing, solder is not completely transferred to a substrate when removing a mask.

In addition, due to the functional diversification and high integration of chips, the IO pin count increases. As a result, the line width and bump pitch of a printed circuit board to be mounted are being significantly reduced. Therefore, the uniform size of solder bumps, such as the height and the volume, become important factors in determining the reliability of the flip chip method.

Therefore, there is a need for a method of forming a solder bump that allows a fine pitch pattern to be applied to a printed circuit board and can form solder bumps having a uniform size.

### SUMMARY OF THE INVENTION

An aspect of the present invention provides a printed circuit board and a method of manufacturing the same that can be applied to a bump layer having a fine pitch and reduce a misalignment between a bump layer and an electrode portion.

According to an aspect of the present invention, there is provided a printed circuit board including: a board portion having an electrode portion provided on a surface thereof; a solder resist layer provided on the surface of the board portion and having an opening therein to expose the electrode portion to the outside; and a bump layer having the same diameter as the opening and providing an electrical connection with an external chip component.

The bump layer may be a plated layer growing into a shape of the opening.

The bump layer may protrude above the opening.

The bump layer may include a copper (Cu) layer.

The board portion may include a plurality of boards stacked upon one another.

According to another aspect of the present invention, there is provided a method of manufacturing a printed circuit board, the method including: forming a solder resist layer on a board portion having an electrode portion thereon; forming a dry film on the solder resist layer; forming an opening in the solder resist layer and the dry film to expose the electrode portion to the outside; and forming a bump layer in the opening by electroplating.

The forming of the bump layer by the electroplating may include: forming a copper post on a lower surface of the board portion; forming a bump layer in the opening formed in an upper surface of the board portion by the electroplating; and removing the copper post.

The forming of the copper post on the lower surface of the board portion may include: bonding a protective film to the dry film; forming copper posts on both surfaces of the board portion; and removing the protective film in order to remove a copper layer formed on the upper surface of the board portion.

The opening may be formed in the solder resist layer and the dry film by laser processing.

The solder resist layer and the dry film may be formed to have the same size.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a printed circuit board according to an exemplary embodiment of the present invention; and

FIGS. 2 through 8 are cross-sectional views illustrating a method of manufacturing a printed circuit board according to an exemplary embodiment of the present invention.

### DETAILED DESCRIPTION OF THE PREFERRED EMBODIMENT

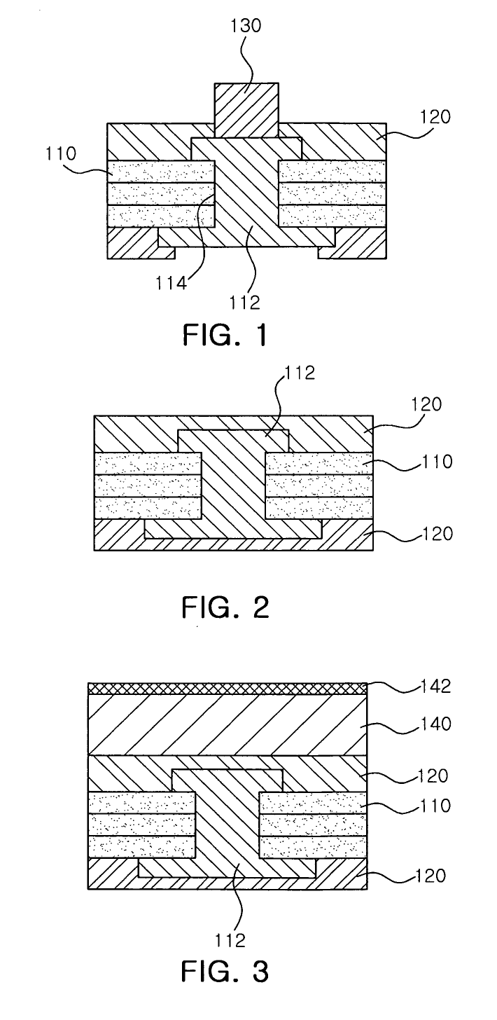

A printed circuit board and a method of manufacturing the same according to exemplary embodiments of the invention will be described in detail with reference to FIGS. 1 through 8. Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions may be exaggerated for clarity, and the same reference numerals will be used throughout to designate the same or like components.

FIG. 1 is a cross-sectional view illustrating a printed circuit board according to an exemplary embodiment of the invention.

Referring to FIG. 1, a printed circuit board may include a board portion 110, solder resist layers 120, and a bump layer 130.

An electrode portion 112 is formed on a surface of the board portion 110 in order to provide an electrical connection with an external semiconductor chip. Here, as for the board portion 110, an organic board portion or a ceramic substrate such as a low temperature co-fired ceramic (LTCC) substrate.

The solder resist layers 120 and the underfill layer 130 may be provided around the electrode portion 112 on the board portion 110. The board portion 110 may have a plurality of layers, and circuit patterns may be formed so that the plurality opf layers are electrically connected to each other.

The electrode portion 112 may be formed on the board portion 110. The electrode portion 112 may fill a via hole 114 in the board portion 110 and thus may be electrically connected to the surface of the board portion 110.

The electrode portion 112 may be formed of aluminum (Al), copper (Cu), tin (Sn), nickel (Ni), gold (Au), platinum (Pt) or an alloy thereof, and may be a multi-layer having copper/gold/nickel stacked in a sequential manner.

The solder resist layers 120 are provided on the surfaces of the board portion 110. The solder resistor layers 120 are formed around the electrode portion 112 to expose the electrode portion 112.

The solder resist layers 120 provide electrical insulation and relieve thermal stress. The solder resistor layers 120 may be formed of an insulating material containing a polymer. Here, the solder resist layers 120 may be formed of an insulating material containing a photosensitive polymer in order to open the electrode portion 112. The electrode portion 112 may be partially opened by performing exposure and development of the insulating material.

Here, in this embodiment, the solder resist layers 120 are formed. However, the invention is not limited thereto, and the solder resist layers 120 may be removed.

The bump layer 130 is formed in the opening 122 in the solder resist layers 120 by electroplating. Further, the bump layer 130 may be formed to have the same diameter as the opening 122 of the solder resist layers 120.

Since the bump layer 130 and the opening 122 have the same diameter, the centers of the bump layer 130 and the opening 122 are naturally aligned with each other. Therefore, a misalignment between the centers of the bump layer 130 and the electrode portion 112 can be prevented. Therefore, a problem that an external chip component and a board portion are not electrically connected to each other in a case of the center misalignment can be solved.

Here, the bump layer 130 protrudes above the opening 122 to allow an external chip component to make contact with the bump layer 130, whereby the bump layer 130 is electrically connected to the external chip component.

Furthermore, the bump layer 130 may be a copper (Cu) layer. Therefore, in order to form the bump layer 130 by electroplating, a copper post may be provided around the opening 122. However, the material of the bump layer 130 is not limited thereto.

FIGS. 2 through 8 are cross-sectional views illustrating a method of manufacturing a printed circuit board according to an exemplary embodiment of the invention.

Referring to FIG. 2, according to a method of manufacturing a printed circuit board, the solder resist layers 120 are formed on the board portion 110 on which the electrode portion 112 is formed.

Here, the solder resist layers 120 are formed by applying photosensitive materials to both sides of the board portion 110. Here, the board portion 110 may include a plurality of boards stacked upon each other. The electrode portion 112 may fill the via hole 114 formed through the plurality of boards.

Referring to FIG. 3, after the solder resist layers 120 are formed on both sides of the board portion 110, a dry film 140 is formed on one of the solder resist layers 120 formed on the board portion 110.

Adhesive power of the dry film 140 may be maintained to prevent a separation between the dry film 140 and the solder resist layer 120.

Here, a protective film 142 is formed on the dry film 140. The dry film 140 is used after removing the protective film 142. In this embodiment, the protective film 142 is not removed.

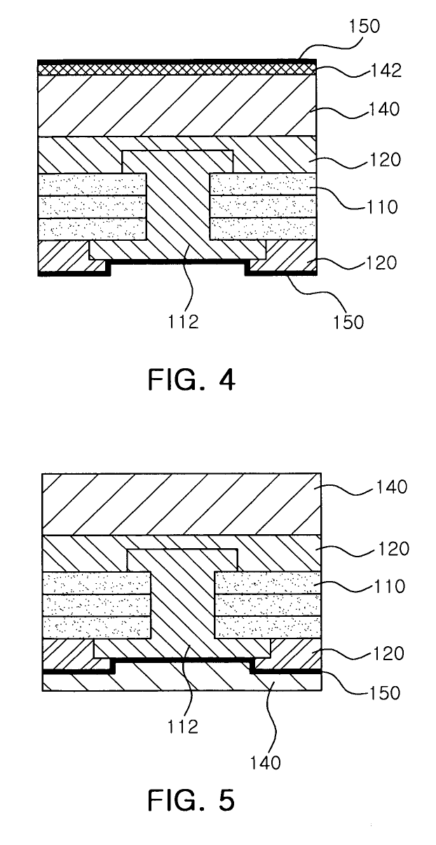

Referring to FIG. 4, as the board portion 110, formed on the dry film 140, undergoes chemical-copper plating, copper (Cu) posts 150 are automatically formed on both sides of the board portion 110.

Here, since the dry film 140 is not formed on a bottom surface of the board portion 110, the copper post 150 may make in close contact with the surface of the electrode portion 112 110 and the board portion 110.

Then, referring to FIG. 5, by removing the protective film 142 formed on the dry film 140, the copper post 150 formed on the protective film 142 may further be removed. The copper post 150 induces the formation of the bump layer 130 formed of copper.

Here, the dry film 140 is formed on the copper post 150 to thereby protect the copper post 150.

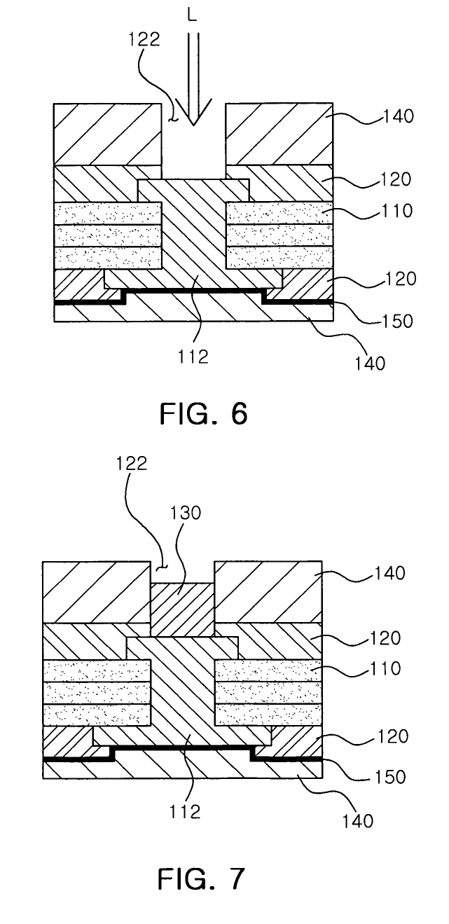

Referring to FIG. 6, the opening 122 is formed in the dry film 140 by laser processing (L) to expose the electrode portion 112. The opening 122 is formed by laser processing (L) so that the dry film 140 and the solder resist layers 120 have the same diameter. However, a method of manufacturing the dry film 140 and the solder resist layers 120 to have the same diameter is not limited to the above-described laser processing.

Referring to FIG. 7, when electroplating is performed on the board portion 110 having the opening 122 therein, currents flow through the other side where the copper post 150 is formed, due to the electrode portion 112 filling the via hole 114 and the copper post 150, so that the materials of the bump layer 130 may naturally fill the opening 122.

Through these processes, the bump layer 130 has the same size as the opening 122 formed in the solder resist layer 120 and the dry film 140.

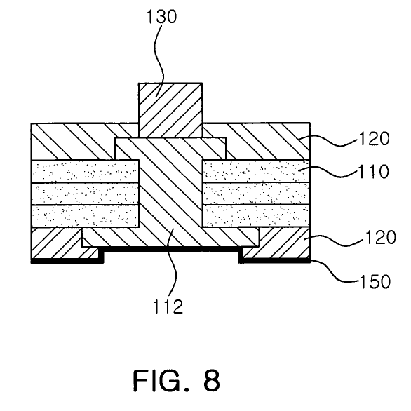

Referring to FIG. 8, after the bump layer 130 is formed in the opening 122, the dry film 140 is removed.

Therefore, when the dry film 140 is removed, the bump layer 130 protrudes above the opening 122 in the solder resist layers 120. Therefore, the external semiconductor chip is easily bonded to the protruding portion of the bump layer 130 and thus is electrically connected to the board portion 110.

When the copper post 150, formed on the lower surface of the board portion 110, shown in FIG. 8, is removed, the printed circuit board, shown in FIG. 1, can be manufactured.

Therefore, the printed circuit board and the method of manufacturing the same according to the embodiments of the invention include the bump layer 130 having the same diameter as the opening 122, thereby realizing the bump layer 130 having a fine pitch.

Furthermore, the printed circuit board according to this embodiment is formed so that the center of the bump layer 130 and the center of the opening 122 coincide with each other, thereby preventing a misalignment between the bump layer 130 and the electrode portion and forming the bump layer 130 having a uniform size, so that a board having high reliability can be provided.

As set forth above, according to exemplary embodiments of the invention, the printed circuit board and the method of manufacturing the same include a bump layer having the same diameter as the opening to thereby realize a bump layer having a fine pitch, prevent a misalignment between the bump layer and an electrode portion, and form a bump layer having a uniform size, thereby providing a board having high reliability.

While the present invention has been shown and described in connection with the exemplary embodiments, it will be apparent to those skilled in the art that modifications and variations can be made without departing from the spirit and scope of the invention as defined by the appended claims.

What is claimed is:

1. A printed circuit board comprising:
a board portion having an electrode portion provided on a surface thereof;
a solder resist layer provided on the surface of the board portion and having an opening therein to expose the electrode portion to the outside; and
a bump layer having the same diameter as the opening and providing an electrical connection with an external chip component.

2. The printed circuit board of claim 1, wherein the bump layer is a plated layer growing into a shape of the opening.

3. The printed circuit board of claim 1, wherein the bump layer protrudes above the opening.

4. The printed circuit board of claim 1, wherein the bump layer comprises a copper (Cu) layer.

5. The printed circuit board of claim 1, wherein the board portion comprises a plurality of boards stacked upon one another.

6. A method of manufacturing a printed circuit board, the method comprising:
forming a solder resist layer on a board portion having an electrode portion thereon;
forming a dry film on the solder resist layer;
forming an opening in the solder resist layer and the dry film to expose the electrode portion to the outside; and
forming a bump layer in the opening by electroplating.

7. The method of claim 6, wherein the forming of the bump layer by the electroplating comprises:
forming a copper post on a lower surface of the board portion;
forming a bump layer in the opening formed in an upper surface of the board portion by the electroplating; and
removing the copper post.

8. The method of claim 7, wherein the forming of the copper post on the lower surface of the board portion comprises:
bonding a protective film to the dry film;
forming copper posts on both surfaces of the board portion; and
removing the protective film in order to remove a copper layer formed on the upper surface of the board portion.

9. The method of claim 6, wherein the opening is formed in the solder resist layer and the dry film by laser processing.

10. The method of claim 6, wherein the solder resist layer and the dry film are formed to have the same size.
